(19) United States
(12) Patent Application Publication
(10) Pub. No.: US 2016/0155870 A1
(43) Pub. Date: Jun. 2, 2016

(54) A SOLAR CELL STRUCTURE AND A METHOD OF ITS FABRICATION

(71) Applicant: SOL VOLTAICS AB, Lund (SE)

(72) Inventors: Ingvar ÅBERG, Staffanstorp (SE); Jonas OHLSSON, Malmo (SE); Damir ASOLI, Oxie (SE); Nicklas ANTTU, Lund (SE)

(21) Appl. No.: 14/896,369

(22) PCT Filed: Jun. 5, 2014
(86) PCT No.: PCT/SE2014/050685

§ 371 Date: Dec. 4, 2015

(30) Foreign Application Priority Data
Jun. 5, 2013 (SE) 1350687-8

(51) Int. Cl. H01L 31/0352; H01L 31/18; H01L 31/0735; H01L 31/0224; H01L 31/0216

(52) U.S. Cl. CPC H01L 31/035281; H01L 31/022466; H01L 31/02167; H01L 31/0735; H01L 31/1852; H01L 31/1884; H01L 31/1868

(57) ABSTRACT

A solar cell structure (1) and a method of its fabrication, the structure comprising an array of elongated nanowires (2) made in a semiconductor material having a direct band gap. Each nanowire (2) has at least a first (3) and a second (4) sections. Said structure comprises a first electrode layer (7) realizing ohmic contact to at least one portion of each first section (3), a second, optically transparent electrode layer (8) realizing contact to at least one portion of each second section. Each nanowire (2) comprises a minority carrier barrier element (6) for minimizing recombination of minority carriers at the contact to the second electrode layer (8).

The disclosure relates principally to a solar cell structure comprising an array of elongated nanowires made in a semiconductor material having a direct band gap.

The market for solar cells is currently dominated by two competing technologies—silicon-based solar cells and thin film solar cells. For the purposes of this application, a solar cell is to be construed as a single diode designed for photovoltaic applications including its electrical contacts and current spreading layers.

Attractive material properties (especially as regards material purity and passivation), refined and simple process technology and low price of raw material have propelled silicon-based solar cells as they combine relatively high efficiencies with relatively low cost. Structurally, the Si-based solar cell may display a range of options. By way of example, a Si-wafer can be about 200 μm thick, has a textured surface and an anti-reflection coating (by e.g. SiNx). The wafer is frequently p-type with a shallow emitter facing the sun, and with a back-surface field generated by in-diffusion of Al or other p-type dopant. Large numbers of Si solar cells are typically connected in series to minimize resistive losses due to high currents. Main disadvantages of wafer based silicon, either mono- or polycrystalline, solar cells are relatively high energy and material use in production, creating long payback times. Here, term monocrystalline designates silicon with a continuous, i.e. unbroken, crystal lattice, whereas term polycrystalline denotes material comprising small silicon crystals. Further, silicon has no clear road map with respect to improving efficiency much beyond the present day champion record of just above 25% energy efficiency.

The other significant market share is claimed by “thin film” solar cell technologies, the most successful one to date being the Cadmium-Telluride (CdTe) solar cell. In thin film solar cell technologies, a material with stronger light absorption characteristics than silicon is deposited in a planar film on a low cost substrate (such as glass). The thickness of the film is approximately 1% of the thickness of a conventional Si-based solar cell. Since the solar cell is created in a material that is typically deposited on top of a substrate, e.g. by Chemical Vapor Deposition (CVD) or sputtering, rather than being the substrate itself, thin film technologies are normally not limited by wafer form factors but can be made in large sheets. Moreover, since the thin film emitter is typically less conductive than the Si-emitter, a transparent conductive oxide (TCO) has to be deposited on the sun-facing side. Compared to Si-based solar cells, thin film technologies offer cost benefits such as low material consumption and scale advantages, as larger substrates may be employed, but suffer, due to the inferior material quality, from lower efficiencies than Si-based solar cells.

The above-cited drawbacks, in particular high energy and material use in production, are significantly remedied by solar cells where light harvesting is vehicled by use of III-V semiconducting materials. More specifically, higher conversion efficiencies paired with low material usage are obtained by means of solar cells made of single crystal thin films of III-V semiconductors, such as GaAs. Indeed, energy efficiency of these cells exceeds 28% for champion cells.

With continuing reference to use of GaAs in solar cell applications, GaAs is the material of choice for single junction solar cells due to ideal properties of its band gap and its high photon absorption. With respect to production considerations, GaAs is a suitable material in single junction solar cell applications due to its low etch rate in hydrofluoric acid. GaAs is also one of the base materials for high efficiency tandem solar cells, i.e. solar cells containing several p-n junctions where each junction is tuned to a different wavelength of light. These are typically based on Ge/GaAs/InGaP and related materials, indicating a path for bringing this technology to efficiencies well exceeding 40%. In this context, these extreme efficiency levels have already been reached for bulk planar III-V tandem solar cells for space applications.

In the context of employing III-V semiconducting materials for light harvesting, further progress in improving the energy efficiency of solar cells is achieved by use of nanowire (elongated nanosized structure) based solar cells. By way of example, GaAs nanowire solar cells, preferably aggregated in an array, may reduce the use of material by almost an order of magnitude compared with thin film solar cells in the same material. Diameter of such a nanowire is frequently 150-200 nm and its length spans between 1-3 μm. These nanowires are typically made in GaAs, but also in InP and other suitable compounds having a direct band gap. Notably, nanowire based solar cells provide a large number of options for tandem cell designs. In spite of the relative immaturity of this technology, strong short circuit currents observed in the III-V-nanowires exposed to direct sun-light show that, in terms of light gathering ability relative to material usage, the nanowires clearly outperform the planar film. One example of such nanowires is disclosed in the scientific article entitled “InP Nanowire Array Solar Cells Achieving 13.8% Efficiency by Exceeding the Ray Optics Limit” to Wallentin et al.

Structurally, and this holds regardless of the materials employed, at least two different types of nanowires for solar cell applications may be distinguished based on the position of the pn-junction. First type is a nanowire with an axially provided pn-junction, i.e. the pn-junction is so configured that the principal direction of current flow across the pn-junction coincides with the axial direction of the nanowire. Second type are nanowires with a radially provided pn-junction, i.e. the pn-junction is so configured that at least a portion of the current flow across the junction is perpendicular to the axial direction of the nanowire, and so that the area of the junction corresponding to said portion of the current flow is larger than the area of other parts of the junction. Further, the junction has an essentially radial symmetry. In conjunction with the above and at least when it comes to GaAs, nanowires with radially provided pn-junction are more widely spread.

State of the art semiconductor nanowires for use in solar cells are typically grown from a costly substrate, frequently called wafer, where after remaining components of the solar cell are integrated on this substrate, rendering hereby this technology very expensive, particularly in case of a III-V-wafer such as GaAs. In conjunction herewith, the most common case is that the nanowire material is the same, or similar to, the substrate it is grown from and integrated on. GaAs-nanowires are, for instance, often grown on a GaAs-wafer. Moreover and in order to reduce manufacturing costs, III-V nanowires, e.g. InP or GaAs, may be grown on a substrate that is a conventional silicon wafer. It is here worth noting that silicon-based semiconductor nanowires, usually also grown on a silicon wafer, are well-known in the art, but hitherto acquired knowledge as regards their manufacture and integration into solar cells isn't readily transferable to the field of semiconductor nanowires in III-V, and other, materials. On the above background and in order to reduce the manufacturing costs, various schemes to recycle the substrate after nanowires have been removed from it have been proposed.

Another disadvantage with respect to wafer-based solar cell technology (both silicon and GaAs-wafers) is that the wafer area itself defines the cell area, which in turn relates to the current level. Thus, additional metallization may be needed to minimize resistive losses in conducting spreading layers such as emitters or transparent conductors. In connection herewith and as briefly discussed above, in thin film based solar cell technology, the final substrate is typically passive and non-conducting, e.g. glass, so that segmentation of the thin film in order to reduce current levels is enabled. This separates the physical size of the used substrate from the current level reached in the solar cell, which results in several advantages—for instance advent of the economies of scale and the possibility to tailor current levels in order to minimize resistive losses in emitter or transparent conducting layers, respectively. Furthermore, the need for metallization grids may be eliminated.

Another issue with nanowire based solar cells integrated on a semiconductor substrate is that the light being transmitted through the nanowire array is wasted as heat once it is absorbed in the semiconductor substrate unless a separate, differently tuned solar cell is fabricated in the substrate itself—a considerable challenge considering known difficulties in integration of dissimilar materials.

At least some of the previously-discussed disadvantages associated with wafer/substrate based solar cell technologies could be addressed by nanowire based solar cells provided that a crystalline wafer can be dispensed with in the final product. This can either be done by, at some point, separating the nanowires from the crystalline substrate (and preferably subsequently reusing the substrate), or by downright avoiding use of the substrate in the chain of fabrication of the structure. For example, by utilizing substrate-free growth techniques such as Aerotaxy™ disclosed in the International Patent Applications PCT/SE2011/050599, PCT/SE2013/050594 and/or a liquid-based nanowire alignment technique, disclosed in the International Patent Application PCT/SE2013/050389, the contents of which are hereby incorporated by reference in its entirety, or by mechanically separating the wires from a substrate, the wires could instead be aligned inside a transfer material—usually a polymer or other, thereto similar material. However, the crucial issue of preserving alignment of such substrate-free wires still needs to be satisfactorily settled.

In the same context, a further issue of controlled contacting of nanowires is raised. More specifically, polymer films required to transfer wires from the alignment surface/substrate to the novel, typically non-crystalline, substrate would normally be deposited by inexpensive methods resulting in some variations of the film thickness. Usually, a portion of the film, into which the nanowires are embedded, is subsequently removed. Given the non-regularity of the film and the size and the sensitivity of the nanowires, it is clear that said removal, mainly through mechanical methods, cannot be effected without great care, if the original alignment of the nanowires is to be preserved. This, in turn, complicates the process step of contacting nanowires by means of electrodes.

A further aspect of nanowire-based solar cells is a high surface-to-volume ratio when compared to planar solar cells belonging to the prior art. This is particularly true for many direct band-gap compound semiconductors of group-III and group-V, respectively. Here and due to its ideal band gap and relative technological maturity, GaAs is of particular interest as a solar cell material, but it is well documented that its surfaces are very poor. More specifically, the high density of surface states depletes the surfaces and causes recombination of minority carriers. As an example, in conventional planar solar cells made of GaAs, heterostructure passivation layers of AlGaAs, GaInP etc. are typically grown on the planar surface to reflect minority carriers which effectively reduce the surface induced recombination. Impact of the surfaces is even more significant if they are intersected by the pn-junction. For nanowire-based solar cells, the additional surface area is found on the sidewalls of the nanowires and accounts for the majority of surfaces. Accordingly, for nanowires with axially provided pn-junctions, all the junctions intersect the sidewall surfaces. This is particularly detrimental for materials such as GaAs with documented poor surfaces. Most prior research on GaAs nanowire solar cells, and many other III-V solar cells, has therefore focused on nanowires with radially provided pn-junctions. In this configuration, the pn-junction is less exposed to the surfaces, and since the depletion region is perpendicular to the solar radiation, short effective lifetimes in the material, being a consequence of the poor surfaces, have less impact on the ability to collect the carriers.

On the above background, nanowire arrays, having nanowires with axially as well as radially provided pn-junctions, seem to be promising candidates when it comes to increasing efficiency while decreasing material usage in solar cells. However, a number of outstanding questions are still to be answered in this respect. Obviously, some of the criteria that need to be satisfied in order to achieve a viable solution in this respect are high throughput and reliability. Moreover, energy efficiency of the novel structures should at any rate match that of the standard solar cells currently available in the marketplace. A further challenge lies in maintaining the alignment of the nanowires and meeting the contacting requirements in view of the top and bottom contacts. This is particularly true in the case where the nanowires are significantly shorter than any support material used to separate the nanowires from the original substrate. Finally, subsequent controlled integration of the separated nanowires onto novel, preferably low-cost, substrates remains a huge challenge.

An objective of the present invention is therefore to provide a solar cell structure that at least reduces some of the drawbacks associated with the current art. An overall object behind the invention is to provide a structure that combine high solar cell conversion efficiencies, e.g. of III-V direct band gap semiconductors, with the low cost of manufacturing of thin film solar cells. In particular, direct band gap semiconducting nanowires can achieve the light gathering capacity approaching that of a planar film, but with nearly an order of magnitude less material. However, such demonstrations have been performed with nanowires integrated on an expensive substrate and don't capture the necessary structural elements for a low cost, high efficiency nanowire solar cell.

The above stated objective is achieved by means of an inventive concept comprising a solar cell structure according to the independent claims, its embodiments according to the dependent claims, and a method for fabricating a solar cell structure.

More specifically, one aspect of the present invention provides a solar cell structure comprising an array of elongated nanowires made in a semiconductor material having a direct band gap, wherein each nanowire has at least a first and a second sections, a first electrode layer realizing ohmic contact to at least one portion of each first section at a bottom end of each nanowire, a second, optically transparent, electrode layer realizing contact to at least one portion of each second section at a top end of each nanowire, characterized in that each nanowire comprises a minority carrier protection element for minimizing recombination of minority carriers at the contact to the second electrode layer.

This aspect of the present invention addresses the issue of minority carrier losses in the part of the nanowire closest to the sun. In III-V semiconductors, a majority of photons are absorbed in the first 100-200 nm of semiconductor material, which also holds true for properly designed arrays of nanowires made from III-V semiconductors, such as GaAs or InP. In a conventional planar solar cell, the top contact (facing the sun) has a very small area compared to the entire top surface area (or junction area), so that the recombination properties of the contact can be dealt with separately from the recombination properties of most of the surface area. In a nanowire solar cell, since these areas are essentially the same from the perspective of each nanowire, the junction area and the area of the nanowire that makes contact to the transparent conductor facing the sun are similar. Thus, the issue of surface property and contact function are intimately tied together in the nanowire solar cell. In early experiments, researchers concluded that minority carrier losses in the emitter layer facing the sun were primarily due to losses within the high doped material. However, based on more recent modelling and experimental work, the inventors behind the present invention have concluded that the nearly infinite recombination of minority carriers at the top contact can severely limit the performance. Thus, the present invention includes a functional element or structure, herein generally referred to as a minority carrier protection element, for the purpose of minimizing these losses. This functional element may comprise a constraint on the length of the semiconductor section extending above the top edge of the depletion region in the p-n junction diode. It may also be a graded dopant profile to provide a surface field to direct the carriers from the top surface. The functional element may also comprise a heterojunction barrier, either semiconducting barriers or dielectric barriers arranged such that minority carriers are reflected and see a chemically improved surface, but majority carriers do not see a barrier, or can tunnel to the transparent conductor.

In one embodiment the invention relates to a solar cell structure comprising an array of elongated nanowires made in a semiconductor material having a direct band gap, wherein each nanowire has at least a first and a second sections, the first section having a first polarity and a doping level that at least exceeds 1*10¹⁸/cm³, wherein said structure further comprises

a first electrode layer realizing ohmic contact to at least one portion of each first section, a second, optically transparent electrode layer realizing contact to at least one portion of each second section, an adhesive layer, optionally conductive, positioned underneath the first electrode layer, and an insulating layer that electrically separates the first and the second electrode layers, each nanowire further comprising a depletion region being adjacent to a top surface of the nanowire and extending at least in the longitudinal direction of the nanowire, wherein the distance between the top surface of the nanowire and the upper boundary of said depletion region is inferior to 180 nm.

A second aspect of the present invention relates to a method for fabricating a solar cell structure comprising an array of elongated nanowires in a semiconductor material having a direct band gap, said method comprising the steps of
providing a first structure on a layer of material, the first structure comprising the array of nanowires and a polymer matrix, said array of nanowires being completely embedded in said polymer matrix,
separating the polymer matrix with the embedded nanowires from said layer of material,
removing a portion of the polymer material so that at least a first extremity of the respective nanowire protrudes from the polymer matrix,
providing a conductive layer that covers the protruding extremity of the respective nanowire,
providing an adhesive layer underneath the conductive layer,
removing completely the polymer matrix by using a solvent,
depositing an electrically insulating layer,
exposing a second extremity of each nanowire,
depositing an optically transparent conductive layer.

A third aspect of the invention relates to a solar cell structure comprising an array of elongated nanowires made in a semiconductor material having a direct band gap, wherein a first electrode layer realizing ohmic contact to at least one portion of a first section at a bottom end of each nanowire, a second, optically transparent, electrode layer realizing contact to at least one portion of a second section at a top end of each nanowire, characterized in that an upper face of the first electrode layer, facing the nanowires, has a plurality of recesses, and that said bottom ends of the nanowires are positioned in these recesses.

In the second and third aspects of the invention, the problem of providing a structure and method to maintain alignment of nanowires when transferred from one surface or matrix (for instance, a wafer or an interface between liquids, or in a polymer membrane) to another, is addressed. Specifically, the problem relates to means for performing the transfer without maintaining any of the original materials in support of alignment. This is important since the initial materials used to maintain alignment are often expensive, as in the case of a III-V wafer, or not suitable for long term sun exposure, as in many polymer materials that may be suitable for harvesting of wires from a wafer, or even too thick relative to the nanowires, again as in many polymer materials that may be suitable for harvesting of wires from a wafer. The alignment is maintained by a particular structure of the conductor making ohmic contact to the section of the nanowire furthest away from the sun. This wrap-around back-contact structure provides mechanical support to the nanowires so that alignment is maintained through the integration even as all the original materials used to maintain alignment are replaced by other, more suitable materials (cost and function) of the final solar cell.

While nanowire solar cell concepts to date, in particular those made from III-V materials, have used active or conductive substrates, the present invention enables integration of several connected solar cells on one single substrate, resulting in scale advantages and reduced losses from metallization layers.

In the following, positive effects and advantages of the invention at hand are presented with reference to the different aspects of the invention.

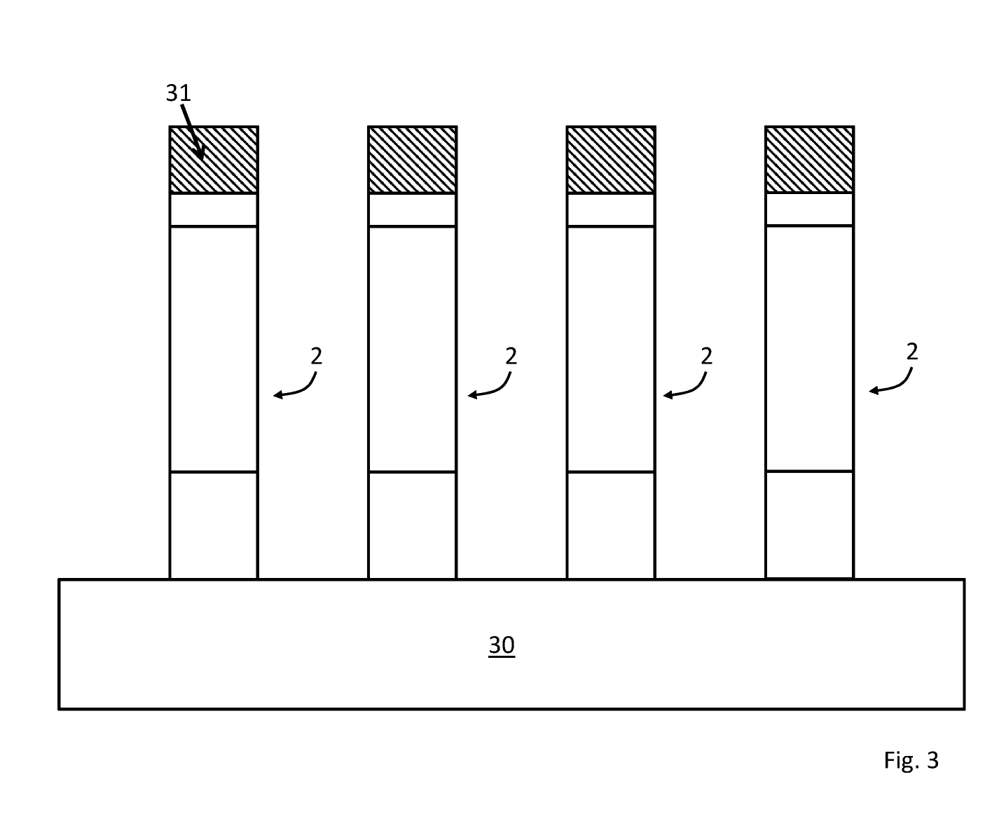

By keeping the distance between the top surface of the nanowire and the upper boundary of the depletion region short the inventive solar cell structure is achieved that is at least as energy-efficient as conventional structures. This is true for structures having an axially as well as a radially provided pn-junction. If the distance from the top surface of the nanowire to the upper boundary of the pn-junction, which more or less coincides with the extent of the high doped region, is inferior to 180 nm, Wallentin et al have showed (see in particular FIG. 3b) that the current was reduced to about 70% of the maximum current observed and even a larger proportion of the simulated peak values of current. This loss, if implemented in a future high efficiency nanowire based solar cell, would limit the efficiency to levels easily obtainable even in mainstream multi-crystalline silicon solar cell technology, severely limiting the future commercial prospects for such cells. The distance between the top surface of the nanowire and the upper boundary of the depletion region is controlled by the thickness of any high doped region near the top of the wire. This region should be kept short—in one embodiment it is less than 150 nm, in order to maintain current response. In a further embodiment, the thickness of the high doped region is less than 180 nm. At any rate, this thickness shouldn't exceed 240 nm. This is an important issue for wafer-free nanowire-based solar cells since layers used to maintain alignment and provide mechanical support are much thicker than the length of the nanowire, and may have non-uniformities larger than 240 nm.

An extreme way to minimize the distance from the topmost part of the wire to the upper boundary of the photo collecting junction is to provide Schottky junction as the top contact. In this case the upper boundary of the depletion region will correspond to the contact interface.

Further, thinning of such layers must end with a very high tolerance. Also, layers used to transfer the nanowires are unlikely to be the best choice for other aspects of integration, such as reliability in a harsh environment. By virtue of the present invention, removal of any such polymer layers with cheap wet strip processes is enabled by introducing a structural design of the bottom conductive layer and using a bond matrix which when combined are able to support the wires and maintain alignment even during wet strip steps. The integration that follows enables the use of additive thin layers with maintained alignment and improved control to meet the challenging tolerance requirements of the solar cell.

It is clear that the obtained solar cell structure is easily transferrable to a substrate of choice, the risk of contamination of the final structure by the traces of material originating from the transfer polymer being eliminated since the polymer matrix is completely removed by means of a solvent.

Further, the structure is accomplished with arbitrary spacing between the wires, i.e. tightly packed wire arrays are not indispensable in order to maintain alignment of the nanowires.

Finally, as the present invention clearly isn't directed to a specific substrate nor a method for providing nanowires, it is clear that the obtained structure may be tailored to any particular size and shape.

Further advantages and features of embodiments will become apparent when reading the following detailed description in conjunction with the drawings.

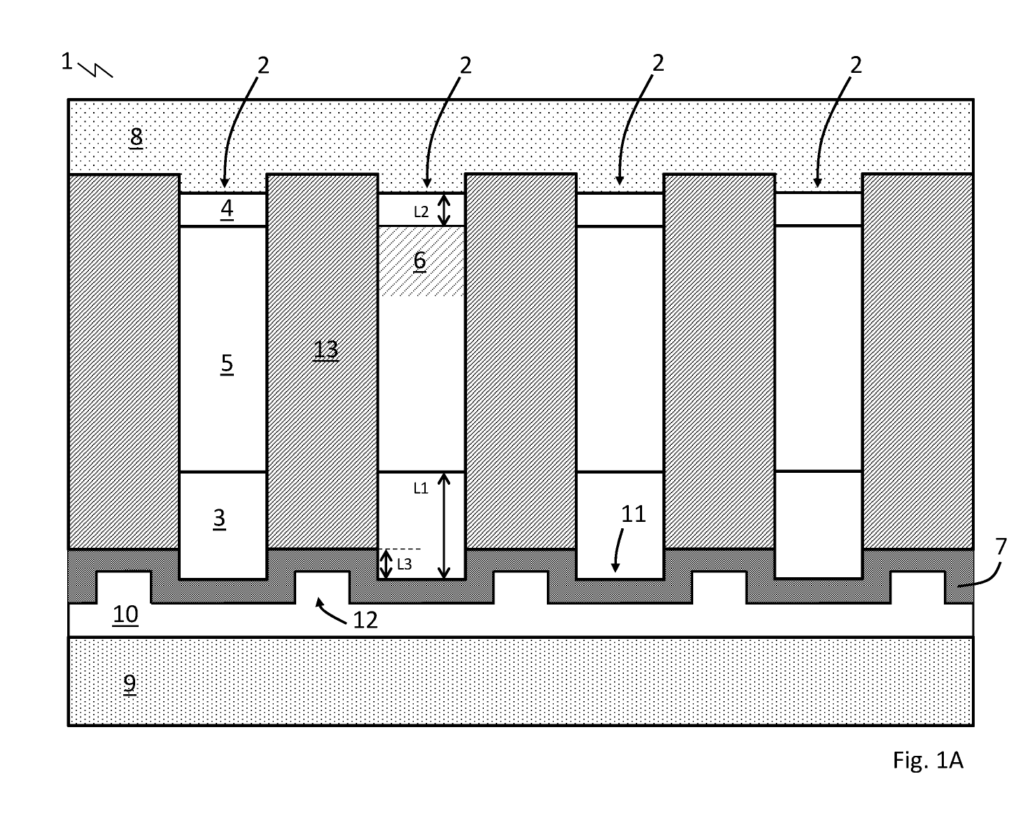

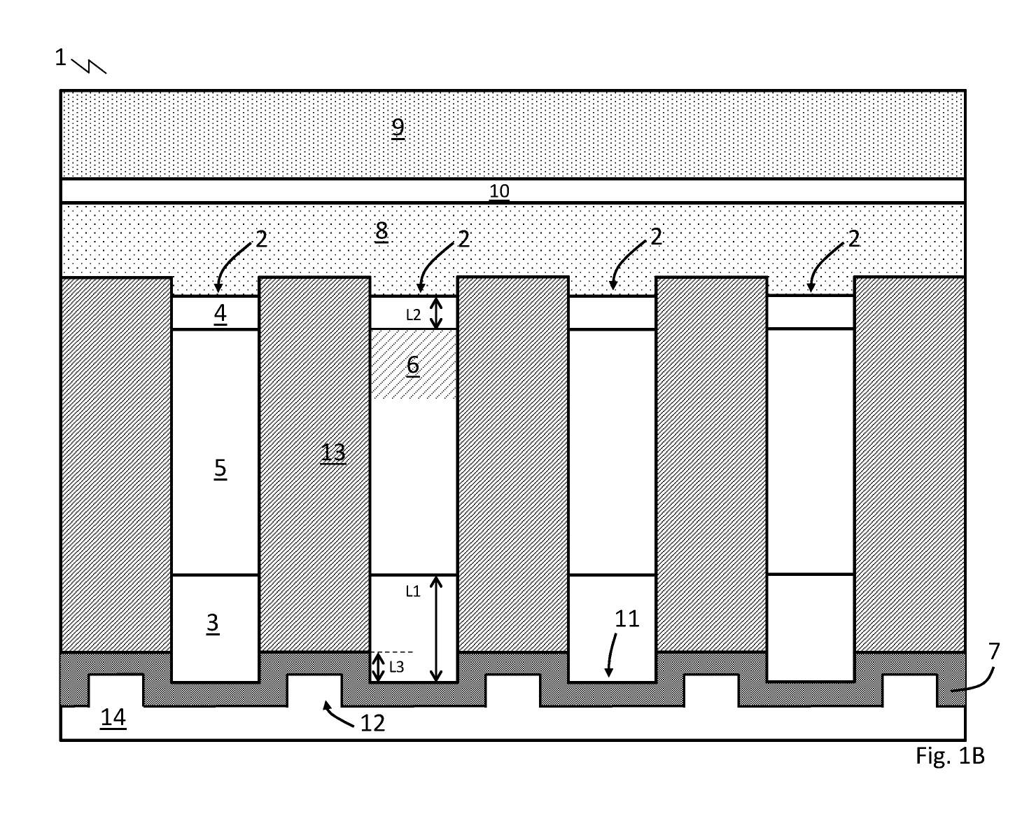

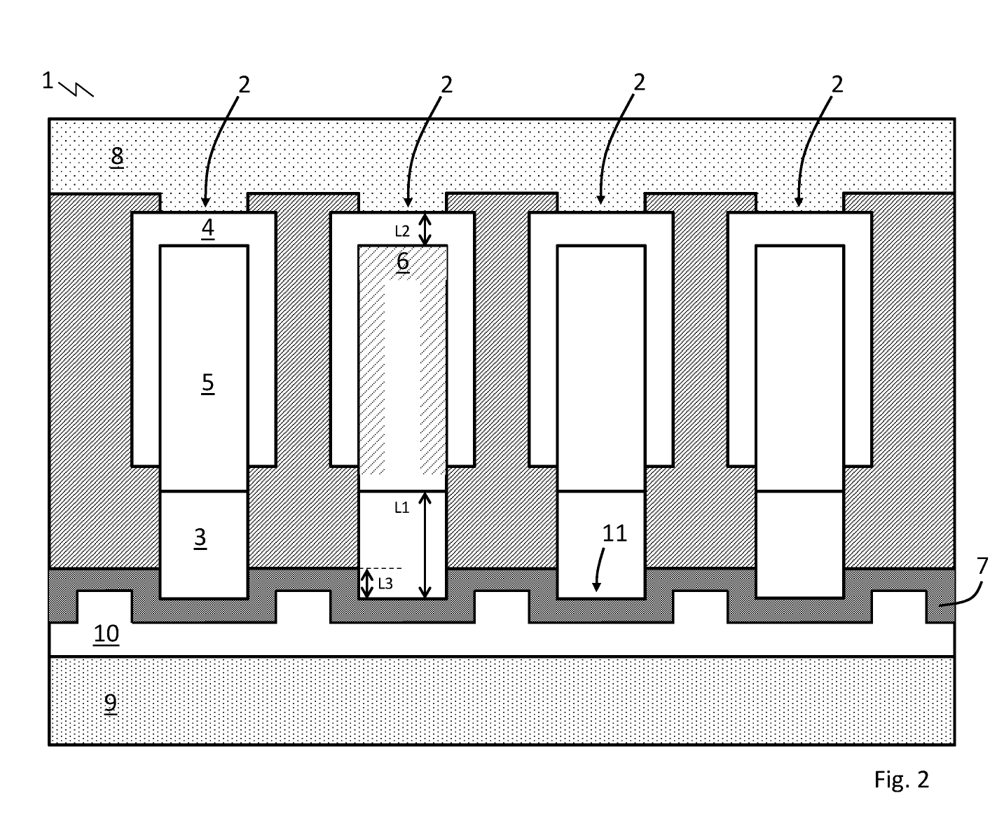

FIGS. 1A and 1B on one hand show an axial implementation, and FIG. 2 on the other hand shows a radial implementation, of the nanowire-based solar cell according to different embodiments of the current invention. The axial implementations of FIGS. 1A and 1B have a 3-section nanowire 2 whereas the radial implementation of FIG. 2 also has a 3-section nanowire, the lowest section extending in the axial direction only.

FIGS. 3-15 show steps of a non-limiting method for manufacture of the solar cell structure of the present invention.

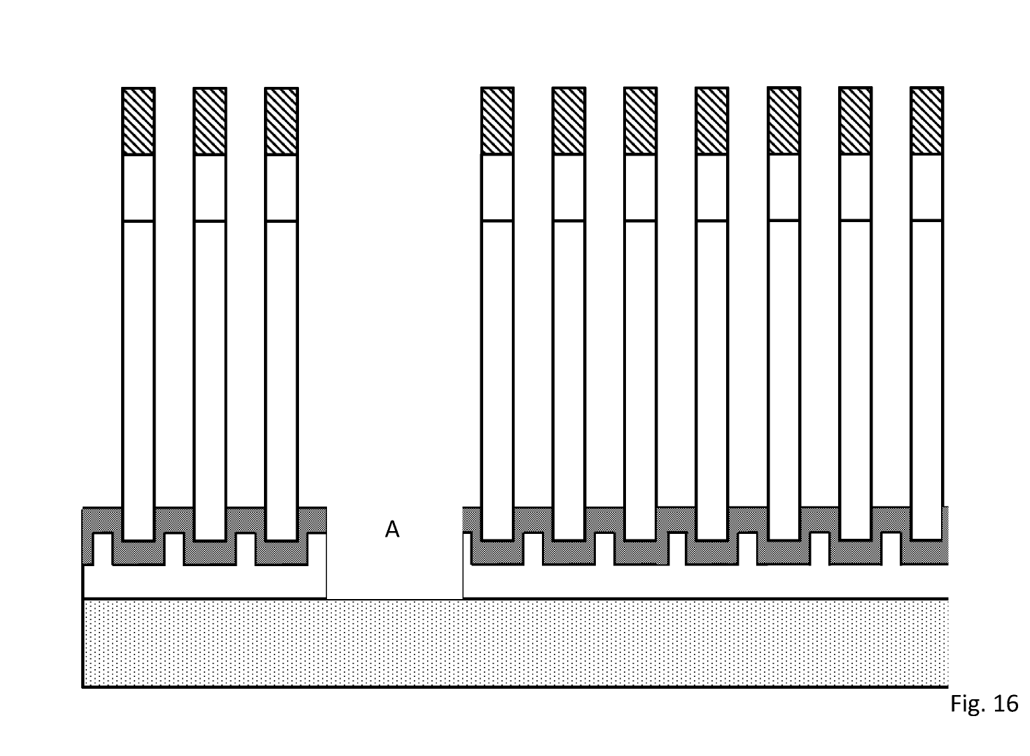

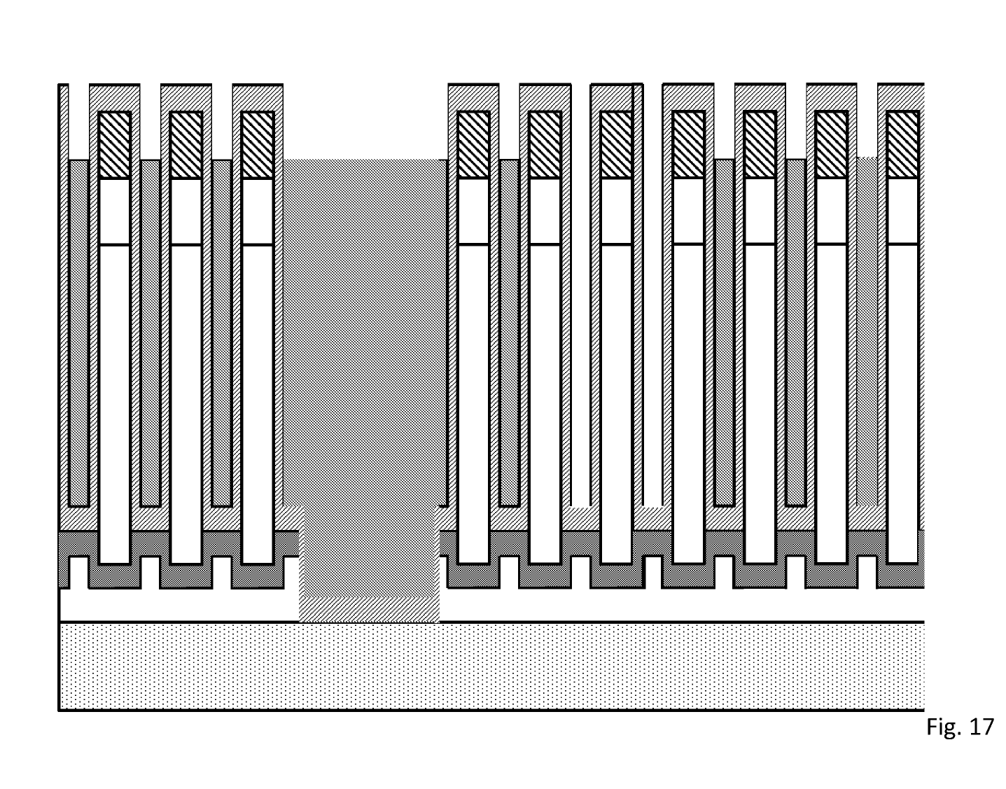

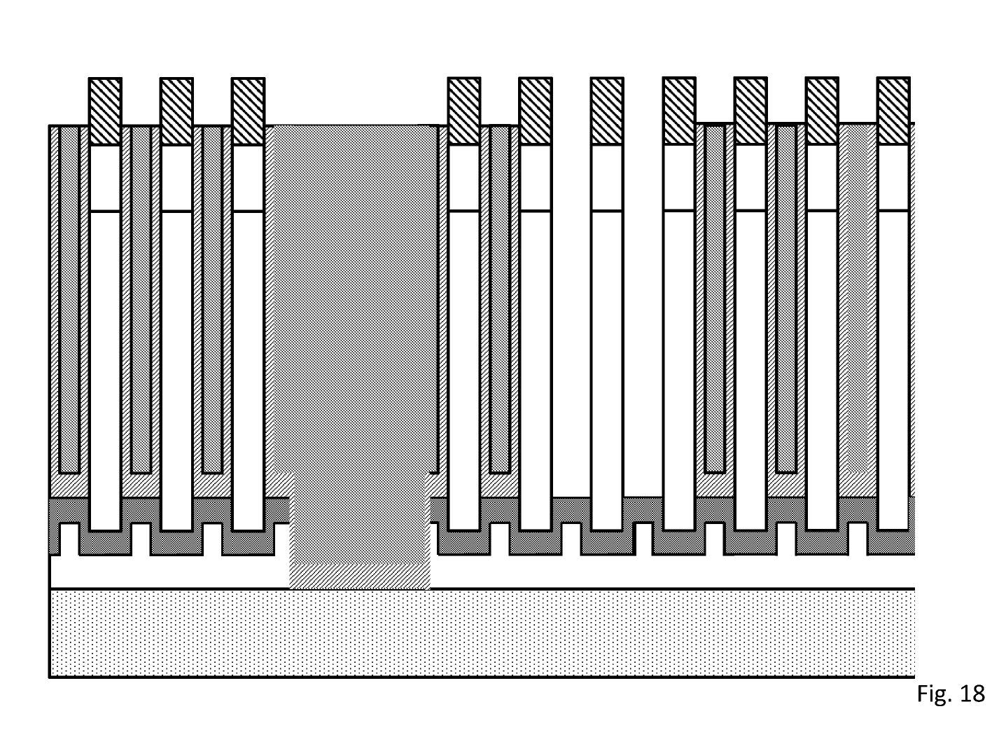

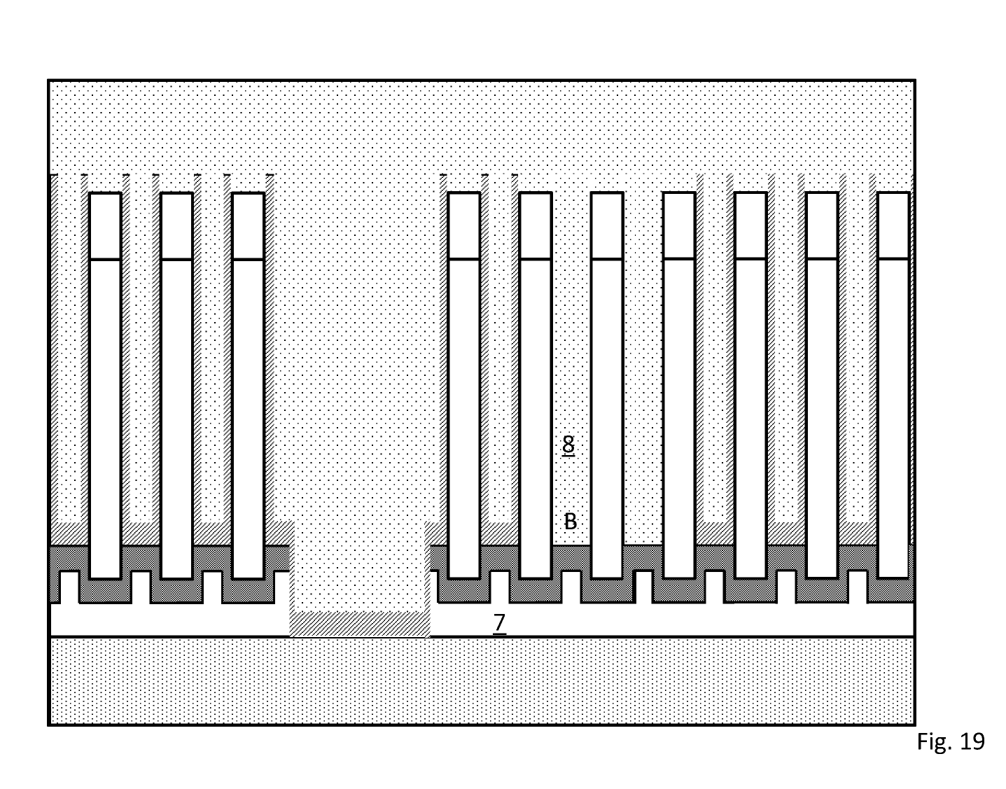

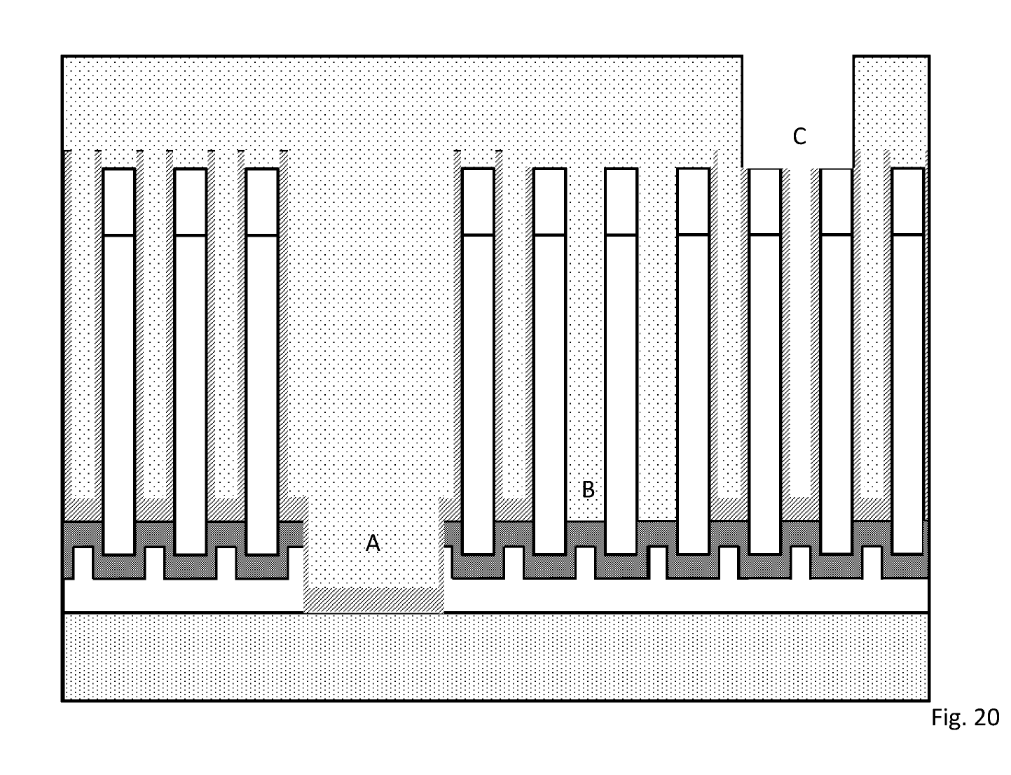

FIGS. 16-20 illustrate a way to serially connect solar cells.

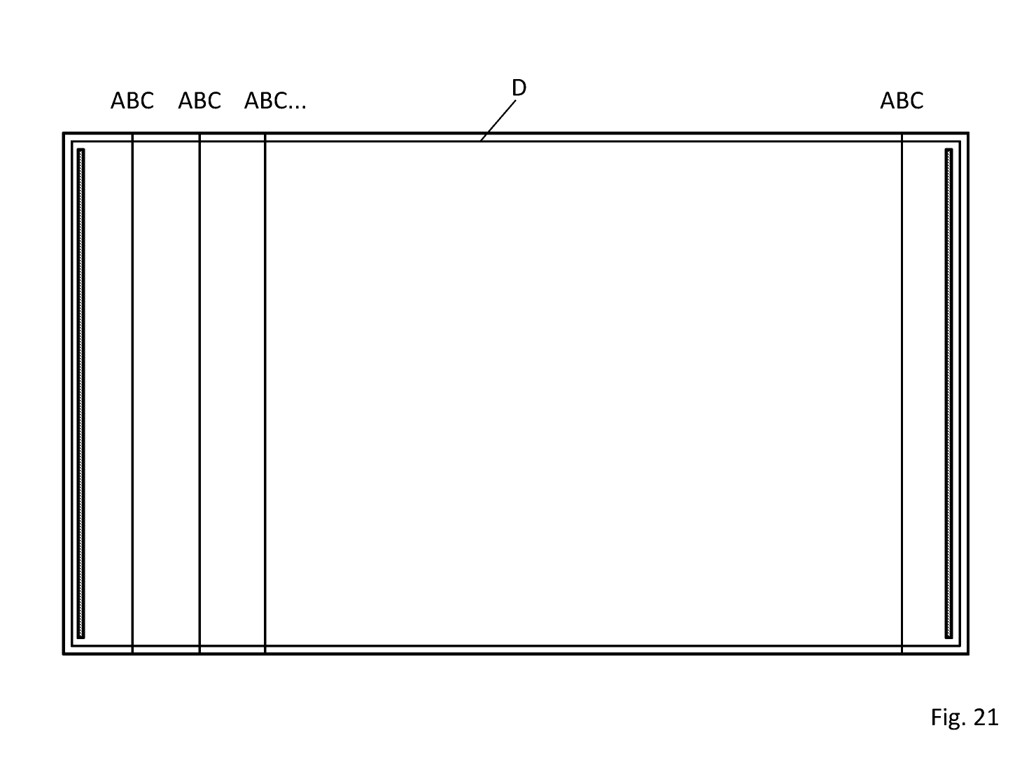

In FIG. 21 multiple series connections are shown on a large module.

The present invention will now be described more fully hereinafter with reference to the accompanying drawings, in which preferred embodiments are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. While reference signs for the structures of the nanowires 2 are only shown in some of the wires, it should be understood that all nanowires 2 of the solar cell structure 1 preferably are identical in terms of disposition. Generally, identical or corresponding elements shown throughout the drawings are referred to by means of the same reference numerals.

FIG. 1A shows a solar cell structure 1 according to an embodiment of the invention. As shown in FIG. 1A, each nanowire 2, extending substantially only in the axial direction, has a first section 3 at a back or lower end of the nanowire 2, and a second section 4 at a sun-facing end of the nanowire 2. The first section 3 is preferably a high doped section of a first polarity, whereas the second section 4 preferably is a high doped section of a second, complimentary, polarity. A first electrode layer 7 realizes ohmic contact to at least one portion of each first section 3 at the bottom end of each nanowire 2. A second, optically transparent, electrode layer 8 makes contact to at least one portion of each second section 4 at a top end of each nanowire. A third section 5 may be arranged between said first 3 and second 4 sections, wherein the first 3 and the second 4 sections have complementary polarities, and wherein doping level of the first 3 and second 4 section exceeds 1*10̂18/cm3 and doping level of the third section 5 is lower than doping level of the first 3 and second 4 sections. The third section 5 preferably has the same polarity as the first section 3. The doping level requirement is to enable ohmic contact formation at low temperature. In an alternative, structurally identical embodiment doping level of the first 3 and second 4 section exceeds 5*10̂18/cm3. A passive, non-crystalline, supporting substrate 9 is arranged as a bottom carrier in this embodiment, attached by means of a bond matrix 10, e.g. an adhesive. In an alternative arrangement, as shown in the embodiment of FIG. 1B, the supporting substrate 9 may instead be arranged on the upper side of the structure 1. Since FIG. 1B shows an embodiment which in most aspects is similar to the embodiment of FIG. 1A, the general description given with respect to FIG. 1A is therefore also applicable to the embodiment of FIG. 1B.

Accordingly, a structure of FIG. 1A is obtained. The structure 1 further includes a minority carrier protection element at the top end of the nanowires 2 for minimizing recombination of minority carriers at the contact between the sun-facing end of the nanowire 2 and the second electrode layer 8.

In one embodiment, it turns out that upper boundary of a hereby created traditional depleted region 6 substantially coincides with the lower limit of the high-doped second section 4 at the top of the nanowire 2 as visualized in FIG. 1A. In order to suitably position the upper boundary of the pn-junction and in order to minimize losses in the emitter, the length requirement L2 for the second section 4 is that it is below 180 nm. The depletion region 6 and the structural length requirement to the contact is an example of a minority carrier protection element, aimed at minimizing losses in the emitter due to minority carrier recombination. The length is here to be interpreted as the axial dimension of the nanowire 2. Positive effects hereby achieved have already been discussed in more detail in conjunction with the discussion regarding independent claims.

As it also may be seen in FIG. 1A, an upper face of the first electrode layer 7 has a plurality of recesses 11 and the nanowires 2 are positioned in these recesses 11. Furthermore, a lower face of the first electrode layer may also have a plurality of recesses 12, the recesses associated with the upper 11 and the lower 12 face of the first electrode layer 7 being uniformly and alternatingly distributed. Mechanical stability of the structure is hereby improved. In the embodiment depicted in FIG. 1A, the nanowires 2 are substantially vertically positioned and mutually parallel. The robustness of the structure is hereby improved as the probability of the good contact between the nanowires 2 and the first electrode layer is enhanced. Preferably, the depth L3 of each recess 11 should be 100 nm or more in order to provide sufficient stability to the nanowires 2 in a process of transferring the structure, as will be described below.

In an embodiment, length L2 of the second section 4 is below 180 nm and length L1 of the first section 3 exceeds length L2 of the second section 4. As discussed above, the length requirement for the wire section closest to the sun, i.e. second section 4, is to minimize losses in the emitter. The length requirement for the first section 3, one farthest away from the sun, relates to mechanical stability of the array. It also needs to be sufficiently long so as to form a back surface field layer shielding the minority carriers in the base region of the cell from the rear contacts. Moreover, the length and doping requirements of the first section 3 are such that an ohmic contact can be made without Schottky depletion layers to the entire contact surface between the wires and the conducting layer. Obviously, at least one of the first 3 and second 4 sections may comprise two different semiconductor materials creating a heterojunction. In addition to these opposite high doped sections and positioned between them, there is at least a lightly doped, third section 5. This section is optimized for carrier absorption/extraction.

In another embodiment, an alternative example of a minority carrier protection element is implemented. In this example, a heterojunction barrier is implemented, configured to reflect minority carriers while allowing majority carriers to pass. (Such a heterojunction is not shown in the drawings, but would be located at the top portion of the nanowires 2.) Such a heterojunction barrier is configured to act as a minority carrier mirror. The heterojunction may comprise a semiconductor barrier, e.g. InGaP, AlGaAs, AlGaP, or it may comprise a dielectric barrier.

In yet another embodiment, a minority carrier protection element is implemented by means of a Schottky junction, preferably a p-Schottky junction, at the contact between the second section 4 of the nanowires 2 and the second electrode layer 8.

Another embodiment of the solar cell structure 1, a minority carrier protection element is implemented by means of a doping barrier of the second section 4 of the nanowires. More specifically, the second section 4 is configured with graded dopant profile, from a higher dopant level at the contact to the second electrode layer 8 to a lower dopant level downwards towards the first section 3.

As visualized in FIG. 2, the nanowires 2 may be two-dimensional, i.e. extend substantially in the radial direction as well.

In a further embodiment, nanowires 2 of the present invention are surrounded by radial passivation layers. On the general level, reduced surface recombination of minority carriers is achieved. In particular, charge carriers of a GaAs cell without these layers will recombine poorly, and the open circuit voltage of such a cell will be low.

In yet another embodiment, the first electrode layer 7 is transparent such that the light may exit the solar cell structure. This renders possible the stacking of the nanowire 2 solar cell 1 on top of a further solar cell of different material, minimizing hereby thermalization losses. Advantageously, these further solar cells may be manufactured separately from the nanowire-based solar cells of the present invention. As an alternative, the first electrode layer 7 is reflective at the interface of the first section 3 and the first electrode layer 7. Said layer 7 than serves as a mirror for transmitted light, which results in a higher quantum efficiency, or alternatively gives the option to use a shorter length nanowire 2 for the same amount of absorbed light resulting in further materials savings.

In a further embodiment, the insulating layer 13 at least radially surrounds the nanowires 2 and at least one of the nanowires 2 is recessed relative said insulating layer 13. Thus, the electrode 8 contact with the nanowires 2 is preferably made only to the top surface of each semiconductor nanowire 2, or with as little as possible contact to the side of the semiconductor nanowire 2, as described above. Further, a benefit of allowing the insulating shell to extend above the top end of the semiconductor nanowire 2 in the final device structure reduces the influence of process variations either due to varying nanowire 2 length or to other process variations. The final device structure may be achieved by incorporating a metal catalyst particle, which is removed during processing. In an alternative embodiment, a passivating shell extending above the top end of the semiconductor nanowire 2 may also be used in core-shell nanowires 2.

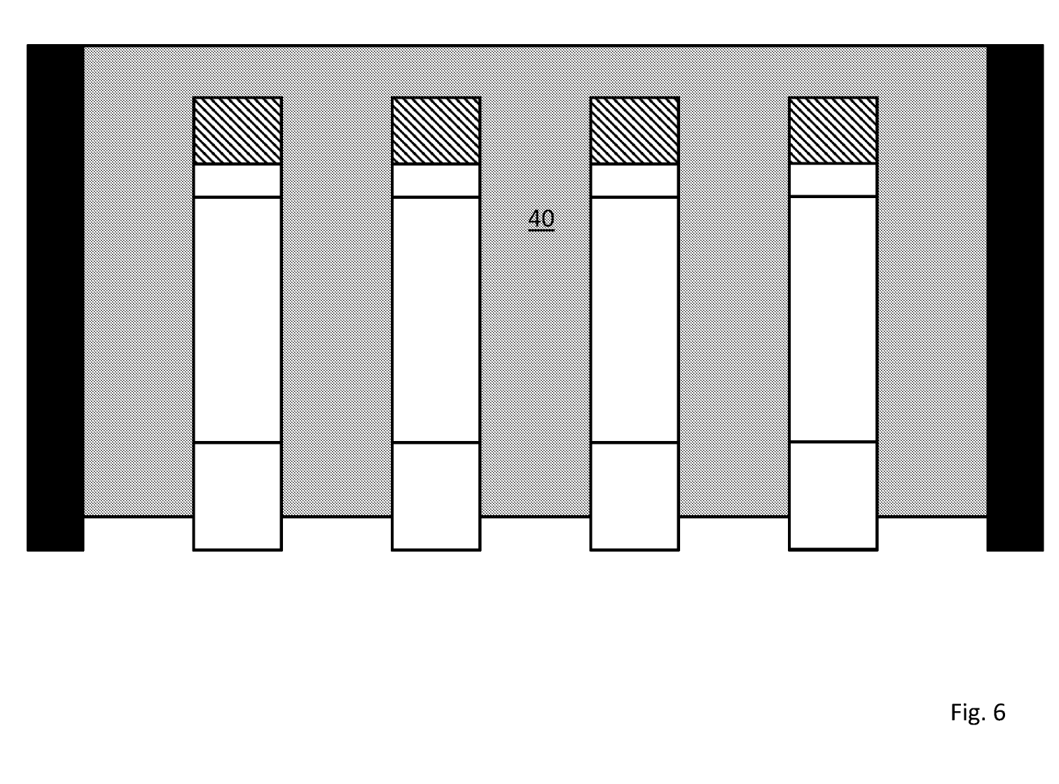

FIGS. 3-15 show steps of a non-limiting method for manufacture of the solar cell structure 1 of the present invention. In particular, FIGS. 3-5 have a contextualizing purpose whereas FIGS. 6-15 are directed at the key steps of the method according to one embodiment of the present invention.

More specifically, in FIG. 3 exemplary GaAs nanowires 2 of 150-200 nm diameter grown by MOCVD on a semiconductor substrate 30, preferably a (111)B GaAs substrate 30 are shown. The growth may be catalyzed by a metallic particle 31, for instance Au. The nanowires 2 grow in the (111)B orientation and thus, they are vertically aligned on the substrate 30. First, a p-type section is grown, followed by an n-type GaAs section such that the p-n junction (not shown) is located near the top of the nanowire, ideally within 180 nm from the top of the wire. The total length of the wire is typically 1-3 μm. The part of the nanowire 2 closest to the substrate 30 (the first grown layer) comprise a section of typically 500 nm worth of highly p-doped material, to later enable non-alloyed ohmic contact formation and back surface field. The p-doping could comprise Zn or C. The topmost part 31 of the wire is a sacrificial material (for instance a VLS-catalyst particle can be used here) of different material composition than the rest of the wire. Accordingly, it can be selectively removed from the nanowire 2—a future recess is hereby created. The growth on the substrate 30 could be done with or without a substrate 30 masking layer.

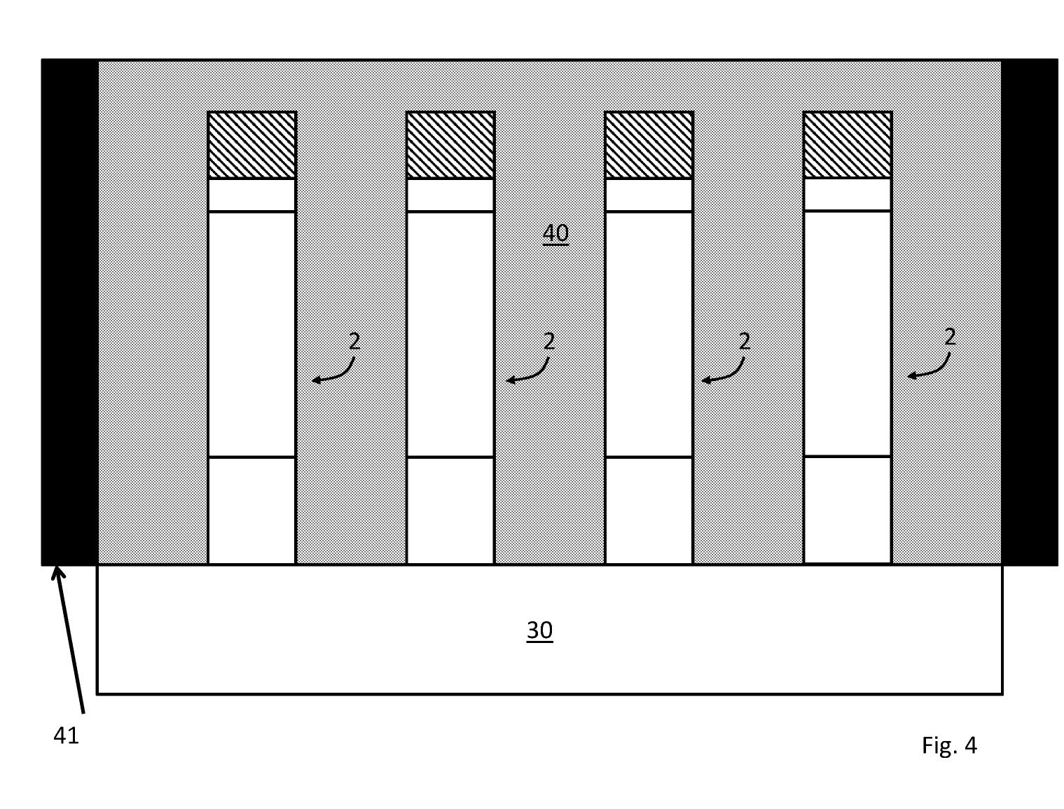

In FIG. 4 a polymer material 40, is deposited on the substrate 30. The deposition of the polymer is typically done by spray-coating. This leaves a polymer film 40 of much greater thickness (for instance >25 μm) than the height of the nanowires 2 (1-3 μm). In addition, a frame 41 may be added in order to facilitate subsequent handling. By spray-coating the film 40 over the edge of the frame 41, the polymer film 40 may be handled more easily at later stages.

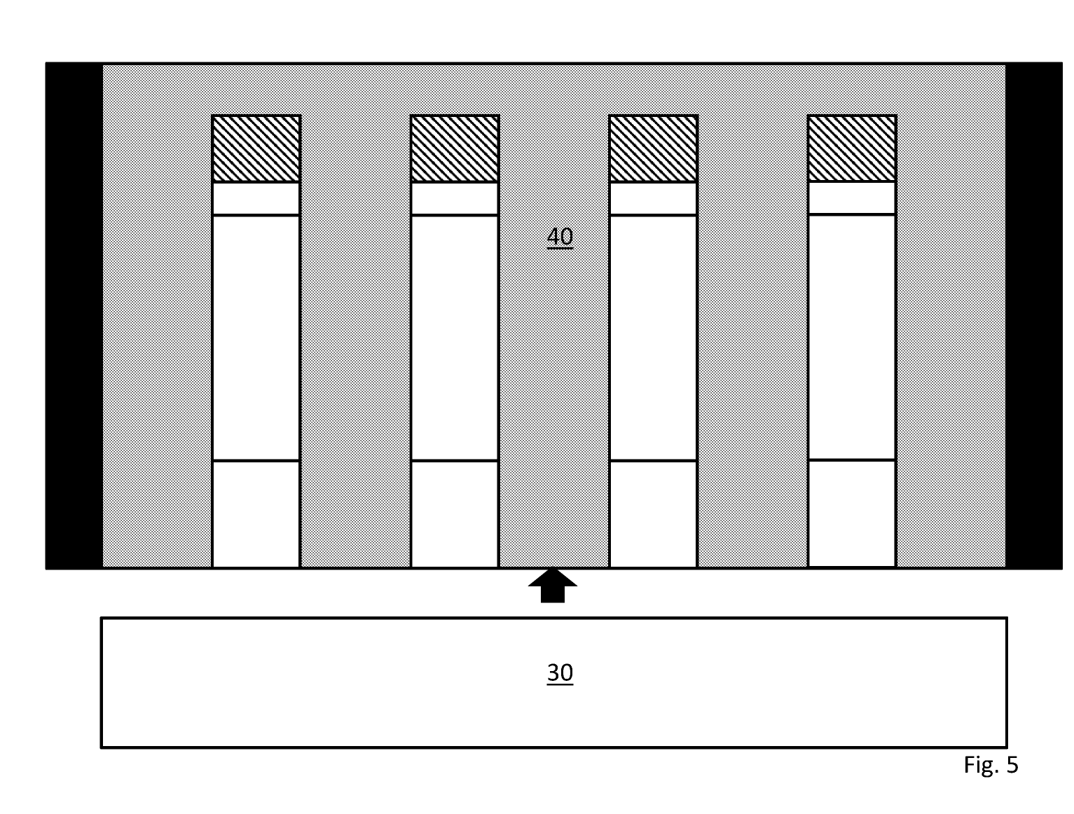

After proper drying, the polymer material is removed by peeling the edges of the film 40 and gradually rolling/pulling the film 40 from the wafer. The frame 41 (or some other temporary handle) reduces the risk that the film 40 is curled up or damaged. After peeling the film 40, the intermediate structure of FIG. 5 is obtained—the nanowires 2 are embedded deep in the film 40 on the front side, while appearing at or close to the surface on the back side.

It is to be understood that the preceding method steps of FIG. 3-5 should not be interpreted as the only way to achieve essentially aligned nanowires 2 in a polymer film 4 or thereto similar material in such a way that the long axis of the wires 2 is perpendicular to two essentially parallel surfaces of the polymer film 40, and in such a way that the nanowires 2 are close to or at the surface of at least one of the surfaces of the polymer film 40. For instance, nanowires 2 could be grown by previously discussed Aerotaxy™ and subsequently aligned using above-mentioned liquid based alignment techniques. Regardless of the method used, the starting point for the method steps of the present invention is that approximately aligned nanowires 2 are available in a substrate-free polymer film 40 such as that illustrated in FIG. 5.

In the following, FIGS. 6-15 directed at the key steps of the method according to one embodiment of the present invention are thoroughly discussed.

An important step for the final structure, illustrated in FIG. 6, crucial for avoiding that the transferred wires fall as well as for enabling good electrical contact is a short etch step performed on the backside. An etch, e.g. O₂-ash, preferentially etches the polymer film 40 so that the nanowires 2 protrude from the film 40 by 100-500 nm once the etch is completed. It should be noted that the length of the protrusion should at most correspond to the length of the lower peripheral high doped region in the nanowire 2.

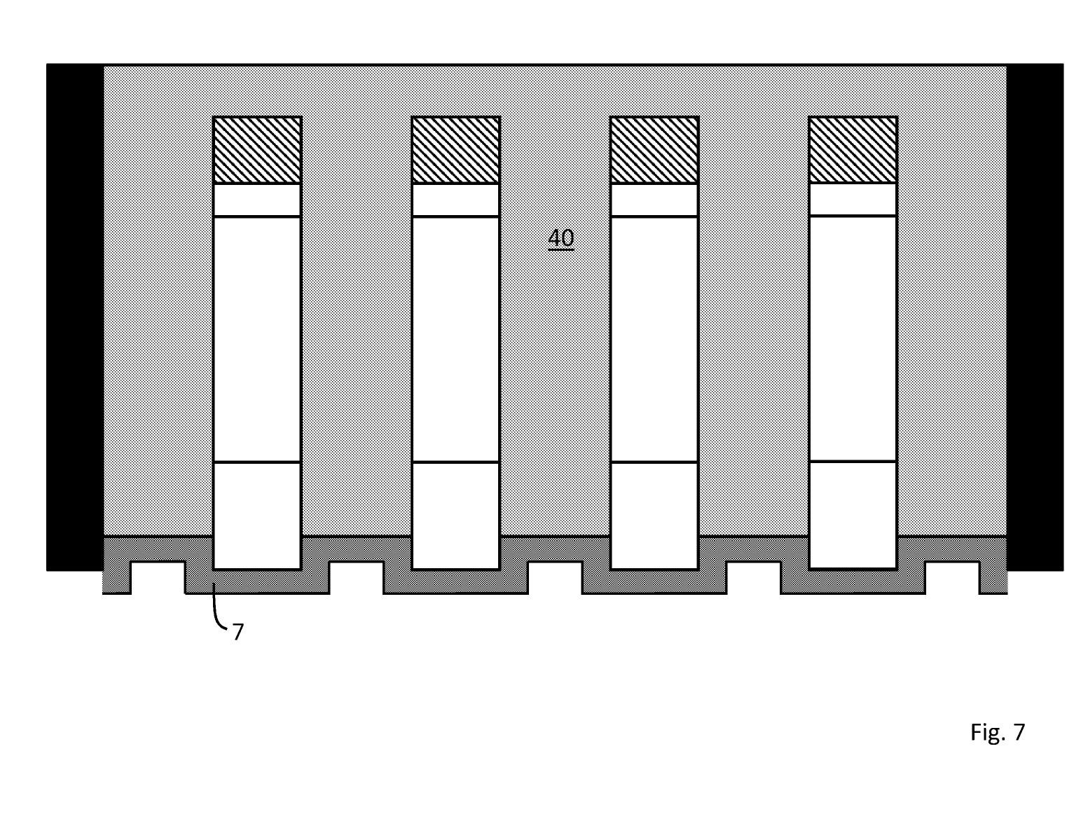

As shown in FIG. 7, a brief native oxide etch-step, for instance in dilute HCl or by a gentle Ar-sputter, has been performed prior to sputter deposition of contact and current spreading layers 7. For instance, the layer 7 may be a Ti/Au/Ti deposition, where the Ti layers may be thin adhesion layers (2-20 nm) and the Au carries most of the current (100-250 nm). However, the deposition is preferably not planarizing, such that coverage between the nanowires 2 is accomplished as well as partly on the side of the nanowire. As can be gathered from the drawings, each nanowire 2 is thereby disposed in a recess 11 in the first electrode layer 7, which provides excellent support and alignment to the nanowires of the solar cell structure 1, especially these steps of production. The current spreading layer 7 may also be a mirror to light not absorbed in the nanowires 2. Other metals may also be used, or transparent conducting oxides if no mirror action is required, for instance if the cell is to be used as a top or intermediate layer in a stacked solar cell.

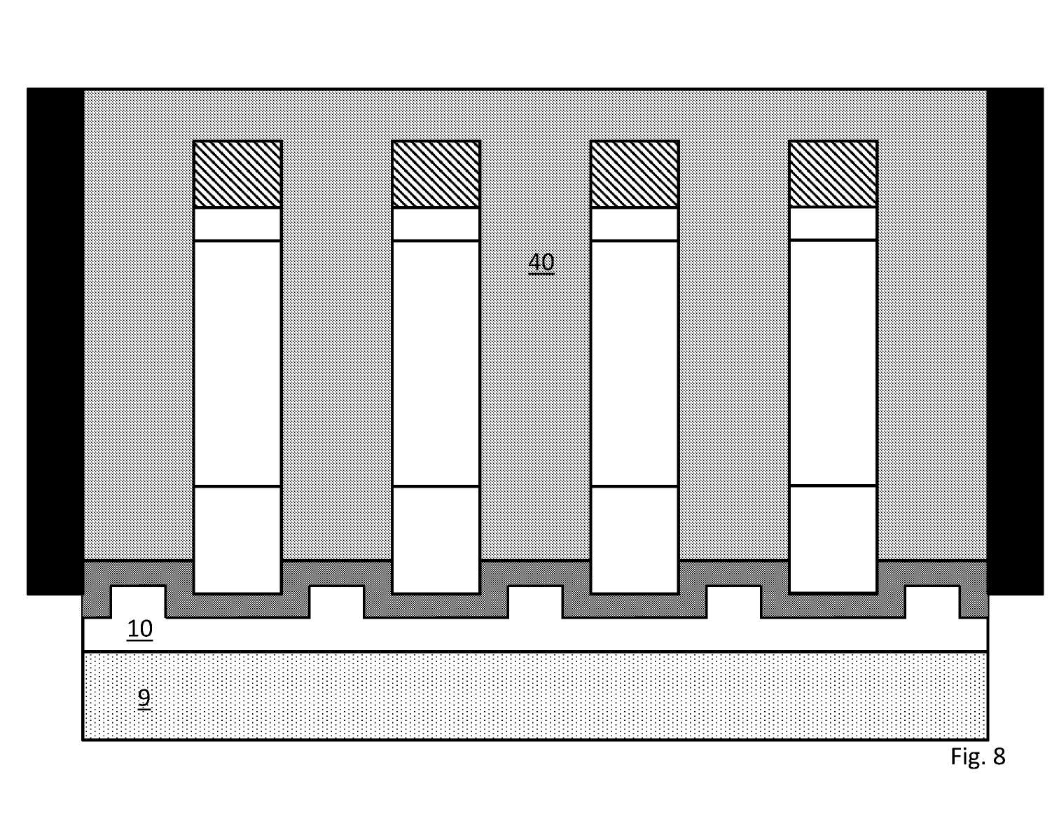

After the rear metallization, the film is bonded to a supporting substrate 9 with a pre-deposited adhesive layer 10, as shown in FIG. 8. A range of materials could be considered for this purpose and might be appropriately selected based on other materials present in the structure. PDMS or other silicone materials could be considered. The adhesive layer 10 is dried or cured.

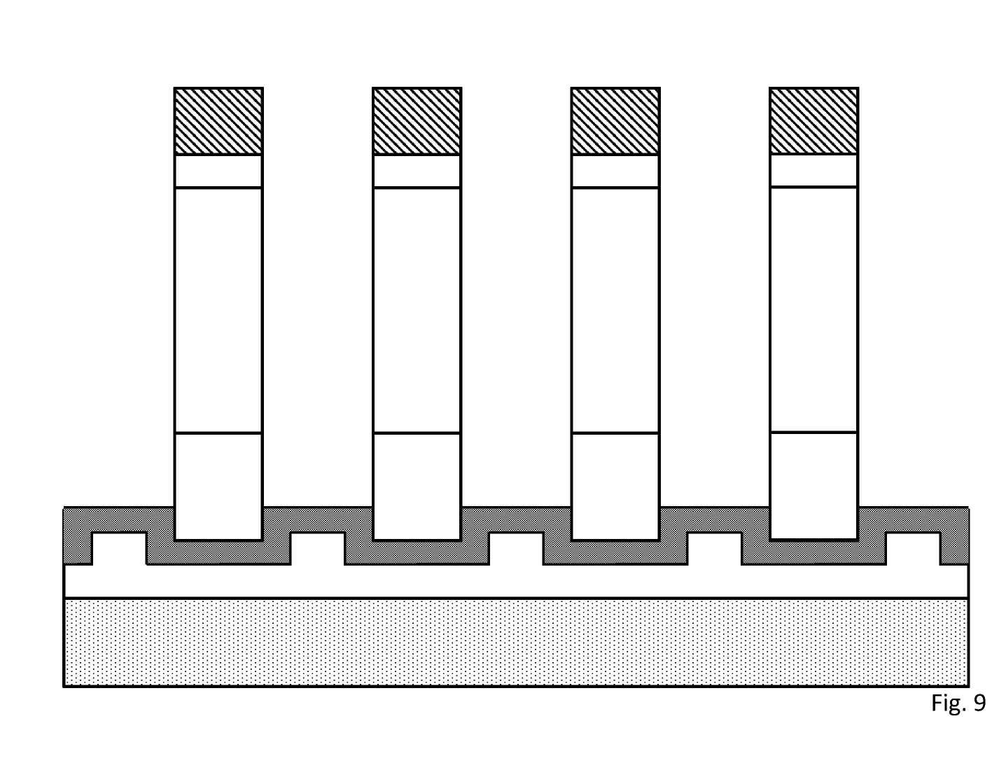

An important step of the method according to the invention, shown in FIG. 9, is that the entire first polymer layer is subsequently dissolved, for instance in a wet solvent. As previously discussed, this solves the issue of tolerance in a thinning step and is also more cost-efficient than a vacuum etch process. This is necessitated since the polymer layer may be of much greater thickness than the nanowires 2, and not necessarily of even thickness. Thus, back-etching or thinning of this thick layer is a difficulty for successful contacting and integration with high yield and low cost. If the wires and ohmic contact/current spreading layers are not properly exposed, the wire alignment and mechanical integrity of the layer stack is not maintained while dissolving the layer. Further the dissolution of the layer ensures that the material suitable for transferring the nanowires 2 does not simultaneously need to meet long term reliability or electrical passivation properties, or compatibility with later process steps. For the dissolution step, it is often an advantage for the nanowire 2 transfer polymer and adhesive layers 10 to be chemically different.

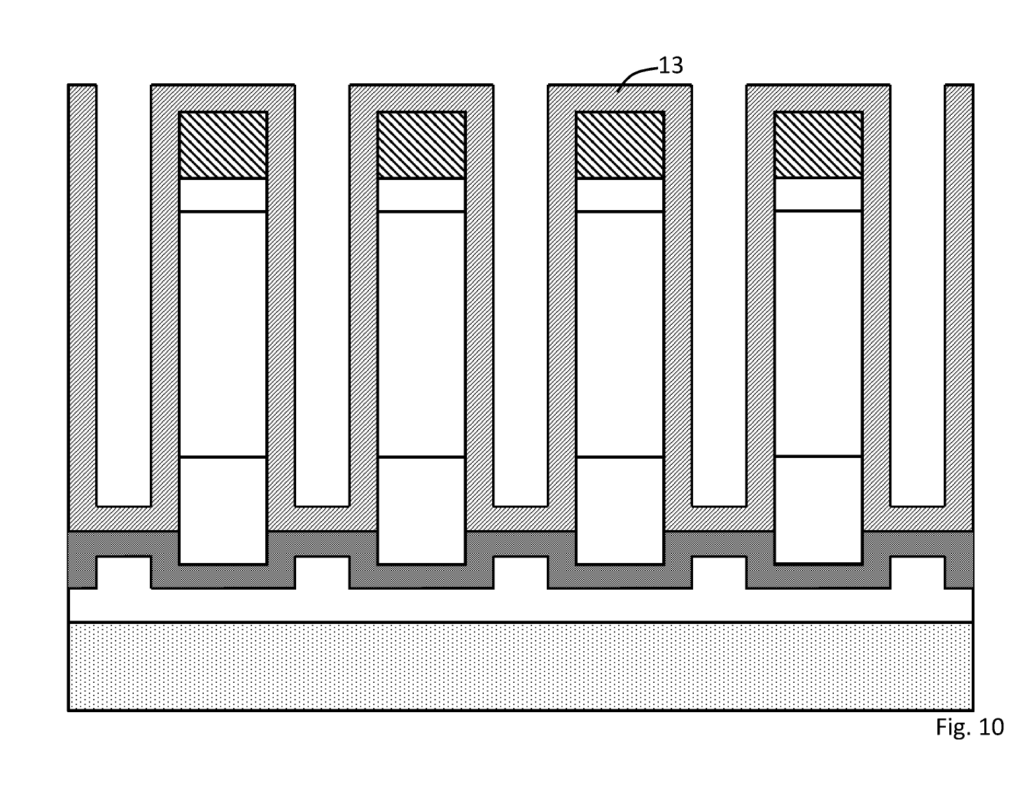

Following the dissolution of the polymer layer, an atomic layer deposition (ALD) of silicon dioxide (SiO₂) takes place (FIG. 10). This film 13 is deposited at 250 C or lower, and is specifically deposited at a temperature compatible with other existing layers in the stack. Alternative dielectrics, or combinations of dielectrics such as Al₂O₃, SiO₂, etc could also be deposited with ALD or other deposition methods. The thickness of this deposition 13 is typically around 50 nm, though other thicknesses should not be ruled out. For instance, if the dielectric is thick enough that the spacing is completely filled by dielectric 13, the structure is equivalent to the previously outlined planar option as shown in FIGS. 1A, 1B and 2. Various spin-on dielectrics such as spin-on glasses or BCB or even photoresist may be used in alternative embodiments.

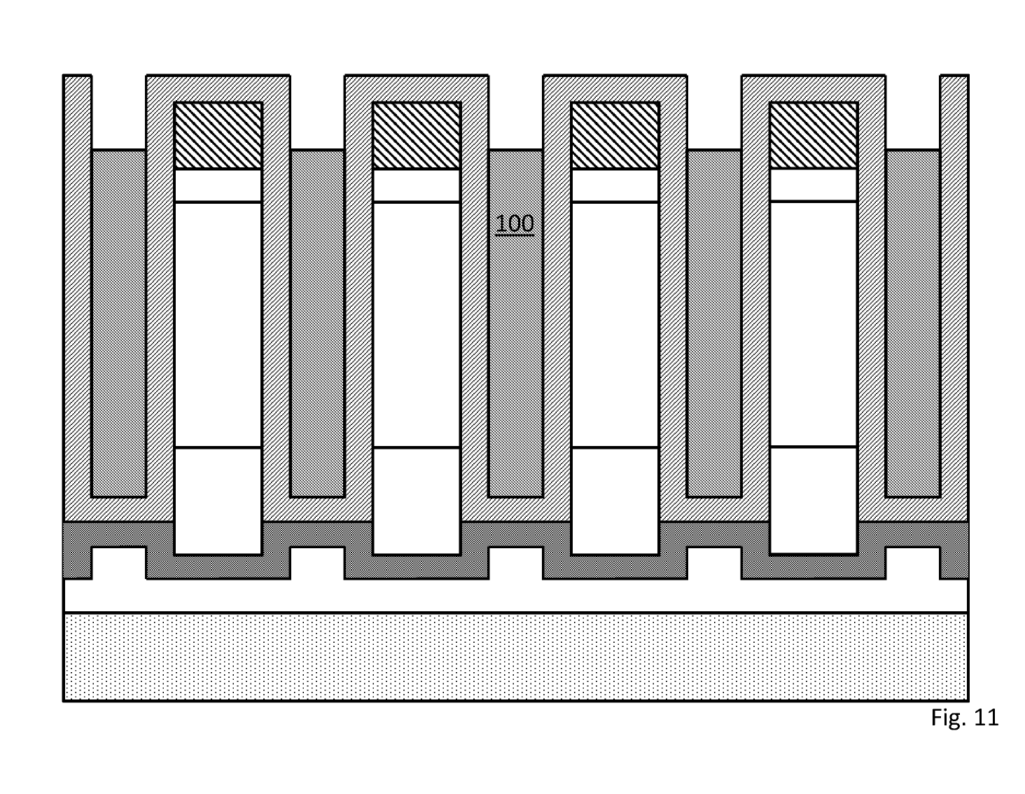

In the next step, visualized in FIG. 11, a photo-resist 100 is spin-coated on the structure to approximately the right thickness. An exposure (for instance by laser) may be performed for purposes of series connecting open circuit voltage of multiple cells, especially in cases where the back substrate 9 and bonding matrix 10 are insulating. This will be discussed later. The photo-resist thickness 100 is adjusted so that it partially covers the sacrificial top portion 31 of the nanowire 2.

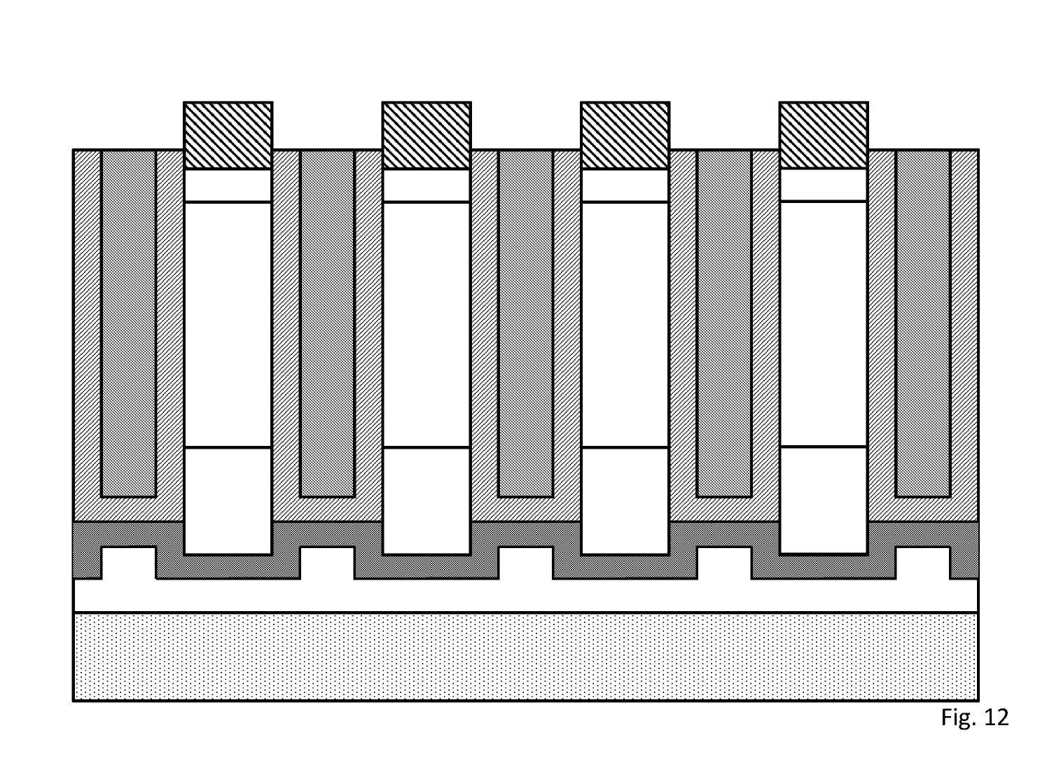

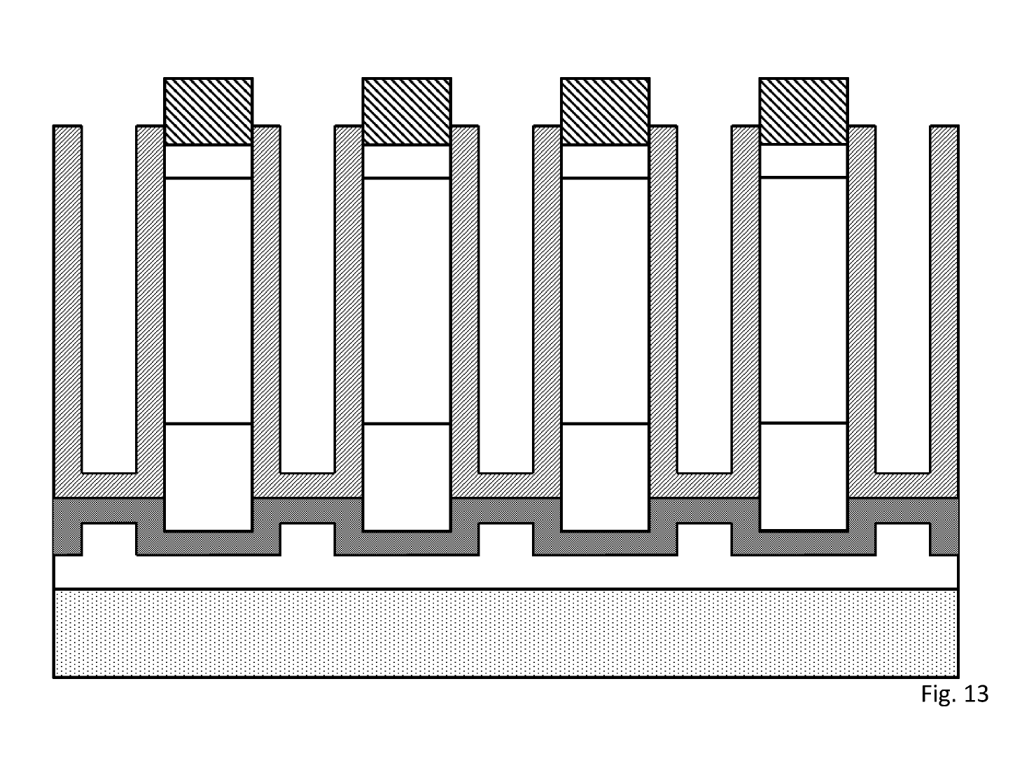

To expose the nanowires 2 for top contacting, the ALD dielectric 13 is etched, ideally with a dry etch which may contain a fluorinated etchant (FIG. 12), after which the photoresist 100 is stripped (FIG. 13). If alternative dielectrics, such as spun-on dielectrics, have been used, other etch chemistries or processes could be performed, but the general concept of a short back-etch in wet or dry chemistry, with or without photoresist masking is performed.

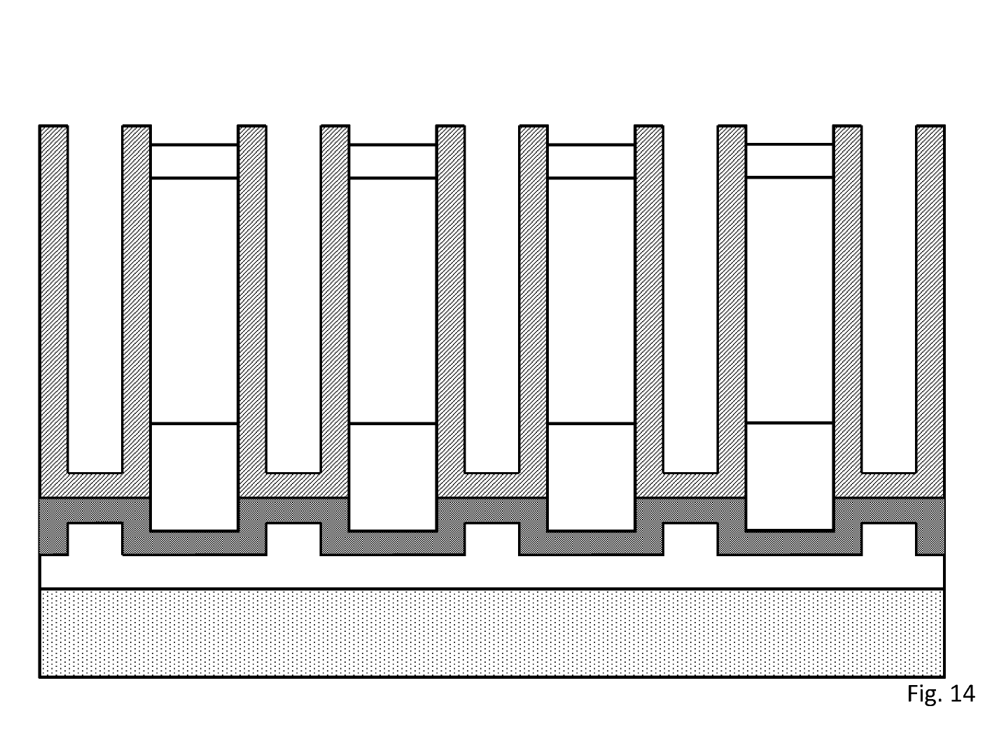

The sacrificial portion 31 of the nanowire 2 is thereafter removed (FIG. 14) by selective etching. If the sacrificial portion 31 of the wire is an Au particle, a potassium cyanide process could be used.

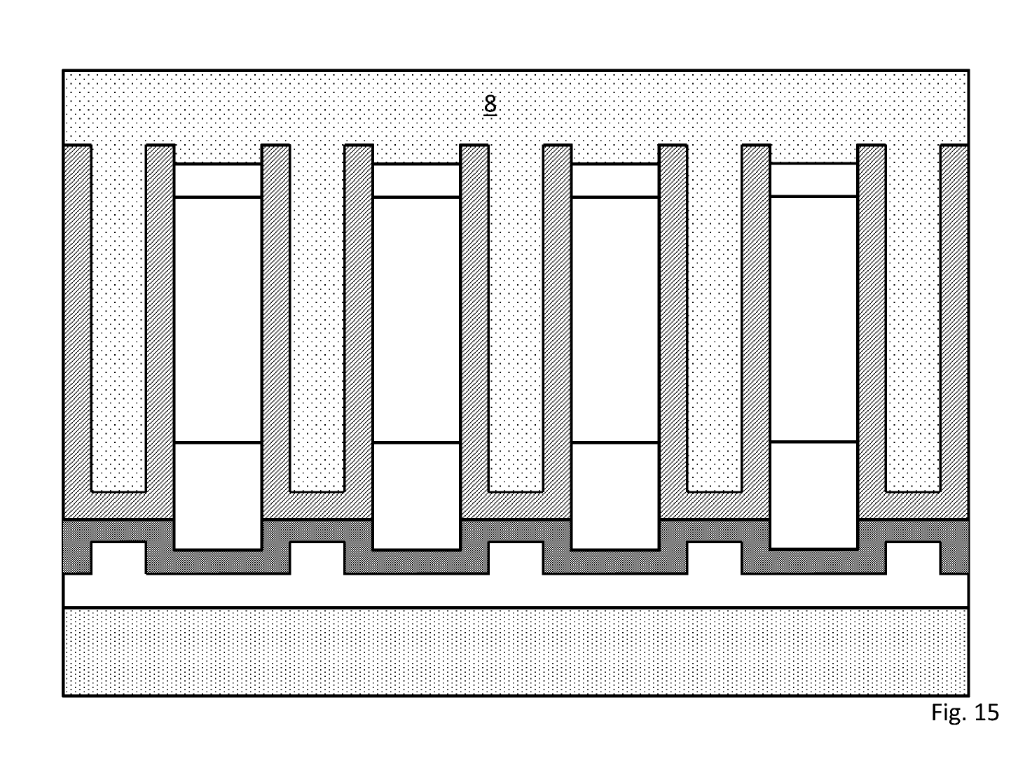

Finally, in FIG. 15, a TCO (Transparent Conductive Oxide) 8 is deposited. Al—ZnO layer, for instance deposited by an ALD process can produce good conformal coverage as in FIG. 15, with complete filling of the spaces between the nanowires 2 as shown, which increases the mechanical stability of the layer and decreases the sheet resistance of the TCO 8. Alternatively, other (low-temperature) TCO films 8 may be considered, for instance sputtered ITO. To produce planar topography, this could be combined with conductive polymers.

In an alternative embodiment, the supporting substrate 9 is instead, or in addition, bonded to the upper face of the structure 1. In such an embodiment, the substrate 9 must be transparent to at least the light intended to be collected by the solar cell structure 1. FIG. 1B shows an example of what such a solar cell structure 1 could look like. There may still be a backing layer 14 disposed to cover the first electrode layer 7, and potentially a further substrate (such as substrate 9 in FIG. 8) of e.g. glass beneath the first electrode layer 7, either as a temporary substrate during production, or as a final additional substrate so as to provide a rigid sandwich structure.

The solar cell bonding matrix 10 and substrates 9 could be conductive, which enables simple top and bottom contact formation, with the addition of top metallization grid by for instance screen printing. Such a solution enables simple cell tabbing as would be the case in a normal wafer based solar cell application. However, if the back substrate 9 is non-conductive (for instance glass), simple tabbing on the backside cannot be performed. In addition, in such a configuration, resistive losses through the back current spreading layer may be too high since a metallic grid cannot be placed on the backside in addition to the thin current spreading layer. In such configurations, front side only tabbing and reduction of the current in the cell are requirements. The current could be reduced by reducing the cell area. For instance, the nanowire 2 array on one shared non-conductive substrate 9 could be divided into several smaller cells, series connected into a module on the same substrate 9. In FIGS. 16-20, one example of such a flow is outlined. The large area cell is converted to a number of series connected cells. The three steps required to carry out one such series connection are shown in FIGS. 16-20. For instance, the back conductor separation A can be done by laser cut. The front to back conductor connection B can be accomplished by dry etching the ALD dielectric in an area cleared of photo-resist by means of a laser exposure. The front conductor separation C can be accomplished by a laser of which wavelength and power is tuned to burn the strongly absorbing nanowires 2 and surrounding TCO film, but leaving the metal layer intact. Optionally, separation C can be done by applying a photoresist and etching the TCO 8. Removal of the wires is not necessary.

In FIG. 21, multiple ABC series connections are shown on a large module. The separation between the ABC connections is determined by the limiting sheet conductivity of either the front or back conductor. The sequence is finished by the edge isolation D which separates both top and bottom conductors around the edge from the active areas, i.e. it is the equivalent of an AC scribe around the edge. Connectors to the junction box of the module can be applied at either end of the module, for instance in the areas indicated. These areas may be screen-printed unless direct soldering can be applied to the TCO.

In the drawings and specification, there have been disclosed typical preferred embodiments of the invention and, although specific terms are employed, they are used in a generic and descriptive sense only and not for purposes of limitation, the scope of the invention being set forth in the following claims.

1. A solar cell structure comprising:
an array of elongated nanowires made in a semiconductor material having a direct band gap, wherein
each nanowire has at least a first and a second sections,
a first electrode layer realizing ohmic contact to at least one portion of each first section at a bottom end of each nanowire, and
a second, optically transparent, electrode layer realizing contact to at least one portion of each second section at a top end of each nanowire, wherein
each nanowire comprises a minority carrier protection element for minimizing recombination of minority carriers at the contact to the second electrode layer.

2. The solar cell structure of claim 1, wherein an upper face of the first electrode layer has a plurality of recesses and the nanowires are positioned in these recesses.

3. The solar cell structure of claim 2, wherein a lower face of the first electrode layer also has a plurality of recesses, the recesses associated with the upper and the lower face of the first electrode layer being uniformly and alternatingly distributed.

4. The solar cell structure of claim 2, wherein said recesses are at least 100 nm deep.

5. The solar cell structure of claim 1, wherein said minority carrier protection element comprises a depletion region adjacent to a top surface of each nanowire, extending at least in the longitudinal direction of the nanowire, wherein the distance between the top surface of the nanowire and an upper boundary of said depletion region is inferior to 180 nm.

6. The solar cell structure of claim 1, wherein said minority carrier protection element comprises a graded dopant profile of said second section, from a higher dopant level at the contact to the second electrode layer to a lower dopant level towards the first section.

7. The solar cell structure of claim 1, wherein said minority carrier protection element comprises a heterojunction barrier, configured to reflect minority carriers while allowing majority carriers to pass.

8. The solar cell structure of claim 7, wherein said heterojunction barrier comprises a semiconductor barrier.

9. The solar cell structure of claim 7, wherein said heterojunction barrier comprises a dielectric barrier.

10. The solar cell structure of claim 1, wherein said minority carrier protection element comprises a Schottky junction forming contact to said second electrode layer.

11. The solar cell structure of claim 1, wherein the contact between the second electrode layer and the at least one portion of each second section is an ohmic contact.

12. The solar cell structure of claim 1, wherein each nanowire has a third section arranged between said first and second sections, wherein the first and the second sections have complementary polarities, and wherein doping level of the first and the second sections exceeds 1*1018/cm3, and doping level of the third section is lower than doping level of the first and second sections.

13. The solar cell structure of claim 1, comprising an insulating layer that electrically separates the first and the second electrode layers.

14. The solar cell structure of claim 1, wherein the nanowires extend substantially only in the axial direction.

15. The solar cell structure of claim 1, wherein the nanowires extend substantially in both the axial direction and the radial direction.

16. The solar cell structure of claim 5, wherein length of the second section is below 180 nm and length of the first section exceeds the length of the second section.

17. The solar cell structure of claim 1, wherein said nanowires are surrounded by radial passivation layers.

18. The solar cell structure of claim 1, wherein at least one of the first and second sections comprises two different semiconductor materials creating a heterojunction.

19. The solar cell structure of claim 1, wherein the first electrode layer is transparent.

20. The solar cell structure of claim 1, wherein the first electrode layer is reflective at the interface of the first section and the first electrode layer.

21. The solar cell structure of claim 13, wherein the insulating layer at least radially surrounds the nanowires and that a top end of at least one of the nanowires is recessed relative said insulating layer.

22. The solar cell structure of any claim 1, wherein the nanowires are substantially vertically positioned and mutually parallel.

23. The solar cell structure of claim 1, comprising an adhesive layer disposed under the first electrode layer, which adhesive layer is bonded to a supporting substrate.

24. The solar cell structure of any of claim 1, comprising an adhesive layer disposed over the second electrode layer, which adhesive layer is bonded to a supporting substrate.

25. A method for fabricating a solar cell structure comprising an array of elongated nanowires in a semiconductor material having a direct band gap, said method comprising the steps:
providing a first structure on a layer of material, the first structure comprising the array of nanowires and a polymer matrix, said array of nanowires being completely embedded in said polymer matrix,
separating the polymer matrix with the embedded nanowires from said layer of material,
removing a portion of the polymer material so that at least a first extremity of the respective nanowire protrudes from the polymer matrix,
providing a conductive layer that covers the protruding extremity of the respective nanowire,
providing an adhesive layer underneath the conductive layer,
removing completely the polymer matrix by using a solvent,
depositing an electrically insulating layer,
exposing a second extremity of each nanowire, and
depositing an optically transparent conductive layer.

26. The method of claim 25, wherein the step of exposing a second extremity of each nanowire comprises removing a portion of the electrically insulating layer so that only a top surface of the second extremity of each nanowire becomes exposed.

27. The method of claim 25 or 26, wherein said layer of material is a substrate and said method further comprises the steps of:
growing an array of substantially one-dimensional nanowires, wherein, for each nanowire,
in a first substep, a first section of the nanowire having a doping level that exceeds 1*10̂18/cm3 and a first polarity is grown from the substrate,
in a second substep, a further section of the nanowire having a doping level that is inferior to 1*10̂18/cm3 is grown onto the first section.

28. The method of claim 27, further comprising the step of
in a third substep, a second section of the nanowire having a doping level that exceeds 1*10̂18/cm3, a second polarity, that is complementary to the first polarity, is grown onto the further section, and the length of the second section is below 180 nm, said length being inferior to the length of the first section.

29. The method of claim 28, further comprising the step of:
in a fourth substep, growing another section of the nanowire onto the second section,
said another section being removed prior to deposition of the optically transparent conductive layer.

30. The method of claim 27, further comprising the step of:
radially passivating the nanowires from outside.

31. A solar cell structure comprising:
an array of elongated nanowires made in a semiconductor material having a direct band gap, wherein
a first electrode layer realizing ohmic contact to at least one portion of a first section at a bottom end of each nanowire, and
a second, optically transparent, electrode layer realizing contact to at least one portion of a second section at a top end of each nanowire, wherein an upper face of the first electrode layer, facing the nanowires, has a plurality of recesses, and that said bottom ends of the nanowires are positioned in these recesses.

32. The solar cell structure of claim 31, wherein a lower face of the first electrode layer also has a plurality of recesses, the recesses associated with the upper and the lower face of the first electrode layer being uniformly and alternatingly distributed.

33. The solar cell of claim 31, wherein said plurality of recesses are at least 100 nm deep.
